(19) United States
(12) Patent Application Publication
(10) Pub. No.: US 2026/0279722 A1
(43) Pub. Date: Sep. 17, 2026

(54) METHOD FOR OPERATING A PARTICLE BEAM DEVICE, AND PARTICLE BEAM DEVICE

(71) Applicant: Carl Zeiss Microscopy GmbH, Jena (DE)

(72) Inventors: Roland SALZER, Leipzig (DE); Alejandro Ramirez PIÑERO, München (DE)

(21) Appl. No.: 19/567,703

(22) Filed: Mar. 16, 2026

(30) Foreign Application Priority Data
Mar. 17, 2025 (DE) 10 2025 110 127.2

(51) Int. Cl. H01J 37/26; H01J 37/22; H01J 37/28

(52) U.S. Cl. CPC H01J 37/265; H01J 37/222; H01J 37/28; H01J 2237/2814

(57) ABSTRACT

A method records an image with high magnification of a structure on a sample using a particle beam microscope. Structure shape information representing a shape of the structure is used to determine an image position of an image representation of the structure in an image of the sample recorded using the particle beam microscope. An operating setting of the particle beam microscope is modified on the basis of the determined image position. The structure shape information is modified on the basis of the determined image position and the recorded image. Subsequently, a new image of the sample is recorded using the modified operating setting. A sequence, which comprises determining the image position, modifying the operating setting, modifying the structure shape information and recording a new image, is performed repeatedly.

### CROSS-REFERENCE TO RELATED APPLICATION

This application claims benefit under 35 U.S.C. § 119 to German Application No. 10 2025 110 127.2, filed Mar. 17, 2025. The entire disclosure of this application is incorporated by reference herein.

### FIELD

The present disclosure relates to a method for operating a particle beam device, and to a particle beam device. The present disclosure discloses for example a method for recording a highly magnified image of a structure on a sample using a particle beam microscope.

### BACKGROUND

A conventional electron beam microscope is used to record images of a sample. In some applications, a sample has an existing structure or a structure is generated on the sample. Subsequently, the aim is to use the electron beam microscope to record an image with high magnification of the structure for the purpose of checking the structure. To this end, an operator first of all operates the electron beam microscope in such a manner that the electron beam microscope records an image with low magnification of the sample, and subsequently the operator locates the structure in the image with low magnification. In order to record an image with high magnification of the structure, the operator increases the magnification of the electron beam microscope. Increasing the magnification means firstly that a distance between adjacent scan points, at which an electron beam generated by the electron beam microscope is directed onto the sample during the recording of the image, is reduced, and secondly that a region of the sample raster-scanned by the electron beam becomes smaller. As the magnification increases, the size of the region of the sample represented by the recorded image therefore decreases.

In general, an image position of an image representation of the structure in the image with low magnification is not the image centre (or another target position), but instead a position at a distance from the image centre. As the magnification increases, the image position of the image representation of the structure generally moves increasingly towards the edge of the image on account of the decreasing size of the imaged region of the sample. In the case of very high magnification, it is thus frequently the case that the image no longer contains the image representation of the structure. In order to counteract this, it is desirable for the operator to gradually adjust the operating setting of the electron beam microscope such that, as the magnification increases, the image representation of the structure is still contained in the image. This is achieved, for example, by controlling a sample stage carrying the sample. However, moving the sample stage leads to problems, for example as a result of the sample stage drifting, especially as the magnification increases.

### SUMMARY

The present disclosure proposes an improved method for recording an image with high magnification of a structure on a sample using a particle beam microscope.

In an aspect, the disclosure provides a method for operating a particle beam device comprising a particle beam microscope. The method comprises: providing a sample, which has a structure on a surface of the sample, in a work region of the particle beam microscope; recording a first structure image, which is an image of the sample that contains an image representation of at least part of the structure, using the particle beam microscope; providing structure shape information that represents at least part of a shape of the structure; and performing a sequence. Performing the sequence comprises: determining an image position, which represents a position of the image representation of the structure in a most recently recorded structure image, using a first image feature recognition process, which uses the structure shape information to recognize the image representation of the structure in the most recently recorded structure image; modifying an operating setting of the particle beam microscope on the basis of the most recently determined image position such that the image position of the image representation of the structure approaches a target image position in a further structure image recorded using the modified operating setting, wherein modifying the operating setting of the particle beam microscope comprises modifying an operating setting of a particle beam deflection of the particle beam microscope and/or modifying an operating setting of a sample stage carrying the sample; modifying the structure shape information on the basis of the most recently recorded structure image and/or on the basis of the most recently determined image position; and recording a further structure image using the particle beam microscope using the most recently modified operating setting. The method further comprises repeating the sequence using the recorded further structure image as the most recently recorded structure image.

In an aspect, the disclosure provides a particle beam device, which comprises a particle beam microscope for recording images, and a controller configured to perform a method according to the disclosure.

### BRIEF DESCRIPTION OF THE DRAWINGS

Embodiments of the disclosure are explained in more detail below with reference to figures, in which:

FIG. 1 shows a schematic illustration of a particle beam microscope according to an embodiment;

FIG. 2 shows a schematic illustration of a particle beam device comprising the particle beam microscope and an ion beam column;

FIG. 3 shows a flowchart of a method for operating the particle beam device according to a first embodiment;

FIG. 4 shows a schematic illustration of a first structure image;

FIG. 5 shows a schematic illustration of a shape represented by structure shape information;

FIG. 6 shows a schematic illustration of an image position;

FIG. 7 shows a schematic illustration of a modified shape represented by the structure shape information;

FIG. 8 shows a schematic illustration of a second structure image and an image position;

FIG. 9 shows a schematic illustration of a further-modified shape represented by the structure shape information;

FIG. 10 shows a schematic illustration of a third structure image and an image position;

FIG. 11 shows a flowchart of a method for operating the particle beam device according to a second embodiment;

FIG. 12 shows a schematic illustration of a sample image;

FIG. 13 shows a schematic illustration of a first structure image; and

FIG. 14 shows a schematic illustration of a distinction image.

### DETAILED DESCRIPTION

### First Embodiment: Particle Beam Device

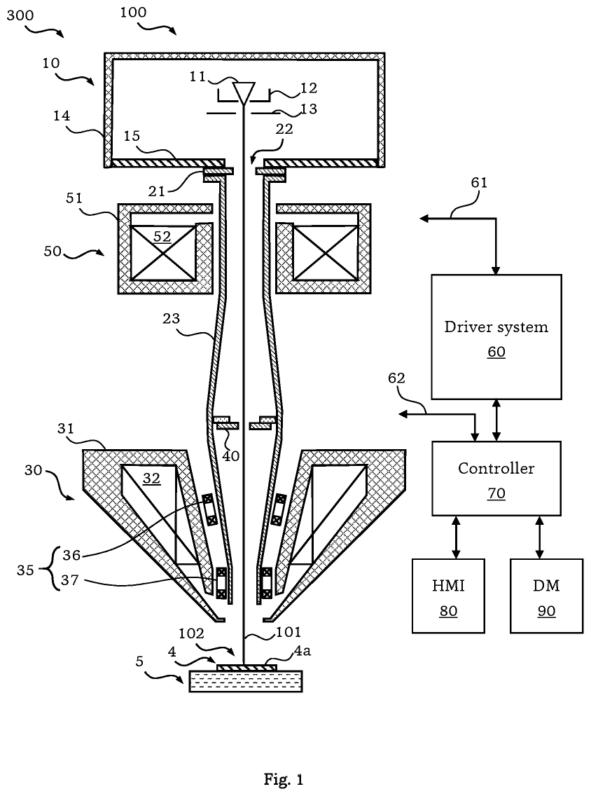

FIG. 1 shows a schematic illustration of a particle beam device 300 comprising a particle beam microscope 100. The particle beam microscope 100 is a microscope that uses a particle beam 101, which is a beam of charged particles. The particle beam microscope 100 is, for example, an electron beam microscope having an electron beam, but can in principle also be an ion beam microscope having an ion beam.

The particle beam microscope 100 comprises a particle beam generator 10 having a particle source 11, which is configured to emit charged particles, a suppression electrode 12, which is configured to block particles emitted thermally by the particle source 11 by applying an appropriate voltage, and an extraction electrode 13, which is configured to extract particles from the particle source 11 by applying an appropriate voltage (for example 0.5 kV to 6 kV with respect to the particle source 11) (referred to as field emission). The extracted particles form the particle beam 101. The extraction electrode 13 is arranged downstream of the particle source 11. The extraction electrode 13 has an aperture through which the particle beam 101 passes.

The particle beam generator 10 further comprises a housing 14, which is used as a vacuum chamber and forms an ultra-high vacuum during operation. In the example shown in FIG. 1, the particle source 11, the suppression electrode 12 and the extraction electrode 13 are arranged within the housing 14 and thus in the ultra-high vacuum. The housing 14 comprises an electrical insulator 15 for electrically insulating the housing 14 from the anode stop 21 described below.

The anode stop 21 having an aperture 22 is arranged downstream of the particle source 11. During operation, the particle beam 101 is directed at the aperture 22 of the anode stop 21. During operation, a voltage is applied to the anode stop 21 in a manner such that the charged particles of the particle beam 101 are accelerated to a kinetic energy of the order of magnitude of 5 keV to 40 keV, for example 8 keV to 30 keV.

The particle beam microscope 100 further comprises the beam tube 23, in which the particle beam 101 travels between the anode stop 21 and an objective lens 30. In the example shown in FIG. 1, the beam tube 23, viewed along a longitudinal direction of the particle beam microscope 100, extends from the anode stop 21 as far as the inside of the objective lens 30. The beam tube 23 and the anode stop 21 are electrically conductively connected to one another.

The objective lens 30 is configured to focus the particle beam 101 onto a sample 4 that is positioned on a sample stage 5. For this purpose, the objective lens 30 comprises for example a magnetic core 31 and an excitation coil 32. The excitation coil 32 is configured to generate a magnetic field that is channeled by the magnetic core 31. The magnetic field leaves the magnetic core 31 through a gap of the magnetic core 31 and is formed, when excited appropriately, such that the magnetic field has a focusing effect on the particle beam 101.

The particle beam microscope 100 further comprises a deflection system 35, which is level with the objective lens 30 and is configured to deflect the particle beam 101 in the radial direction, in order thereby to direct the particle beam 101 onto different locations on a surface 4a of the sample 4. The deflection system 35, in the example shown in FIG. 1, comprises two deflection units 36 and 37, which are formed from coils. In the example shown in FIG. 1, the coils of the deflection units 36 and 37 are arranged between the beam tube 23 and the magnetic core 31 of the objective lens 30. The two deflection units 36 and 37 are arranged in a manner distributed along the longitudinal direction. The spatial region into which the particle beam 101 can be directed by the deflection system 35 is referred to as the work region 102 of the particle beam microscope 100.

The particle beam microscope 100 further comprises a detector 40 for detecting interaction products created by the interaction between the particle beam 101 and the sample 4. In the present example, without loss of generality, the detector 40 is designed in the manner of a stop having an aperture and arranged inside the beam tube 23 upstream of the objective lens 30. The particle beam 101 emanating from the particle source 11 passes through the aperture of the detector 40 and is focused on the sample 4 by the objective lens 30. Interaction products are emitted by the sample 4 as a result of the interaction between the particle beam 101 and the sample 4. In the case of an electron beam microscope, the interaction products are, for example, backscattered electrons or secondary electrons. In the case of an ion beam microscope, the interaction products are, for example, backscattered ions, secondary ions or secondary electrons. Radiation (for example light in the form of fluorescence, cathodoluminescence, etc. or X-ray radiation) may also be emitted and detected as a result of the interaction between the particle beam 101 and the sample 4. In the example of FIG. 1, charged particles emitted by the sample 4 enter the beam tube 23 through the objective lens 30 and can be detected by the detector 40. The detector 40 generates a detection signal, which is based on the detections of the interaction products. The detection signal is, for example, a detection rate. A controller 70, which will be described below, receives the detection signal of the detector 40 via a line 62.

The particle beam microscope 100 further comprises a condenser 50, which is configured to variably set a divergence angle of the particle beam 101. As shown by way of example in FIG. 1, the condenser 50 may be or comprise a magnetic lens comprising a magnetic core 51 and an excitation coil 52.

The particle beam microscope 100 further comprises a driver system 60, in order to supply the components of the particle beam microscope 100 and the sample 4 with the desired voltages and electric currents. The driver system 60 may comprise one or more voltage sources and/or one or more current sources that provide the desired voltages and currents. The driver system 60 generates for example the voltages and currents for the particle source 11, the suppression electrode 12, the extraction electrode 13, the anode stop 21, the beam tube 23, the excitation coils 32, 52, the deflection system 35 and the sample 4. A schematic line 61 represents all of the lines that are used to guide the voltages and currents from the driver system 60 to the components of the particle beam microscope 100 and the sample 4.

The particle beam microscope 100 further comprises the controller 70 for controlling the particle beam microscope 100 and the individual components thereof, for example for controlling the driver system 60. The controller 70 is configured to carry out methods described herein. The controller 70 may comprise one or more processor(s) for executing various programs stored in a memory, for example a data memory 90, which will be described below. By executing the programs, the controller 70 causes methods described herein to be performed. The controller 70 may be implemented by a single device or a plurality of devices.

The particle beam microscope 100 further comprises a human-machine interface (HMI) 80. The HMI 80 is used for receiving inputs from an operator and transmitting them to the controller 70. The HMI 80 is also used for outputting data to the operator, for example a current state of the particle beam microscope 100, detection results generated by the detector 40 and images generated by the controller 70. The HMI 80 comprises, for example, one or more input devices, such as, for example, a keyboard, a mouse or other operating elements. The HMI 80 comprises, for example, one or more output devices, such as, for example, a display device (for example a monitor).

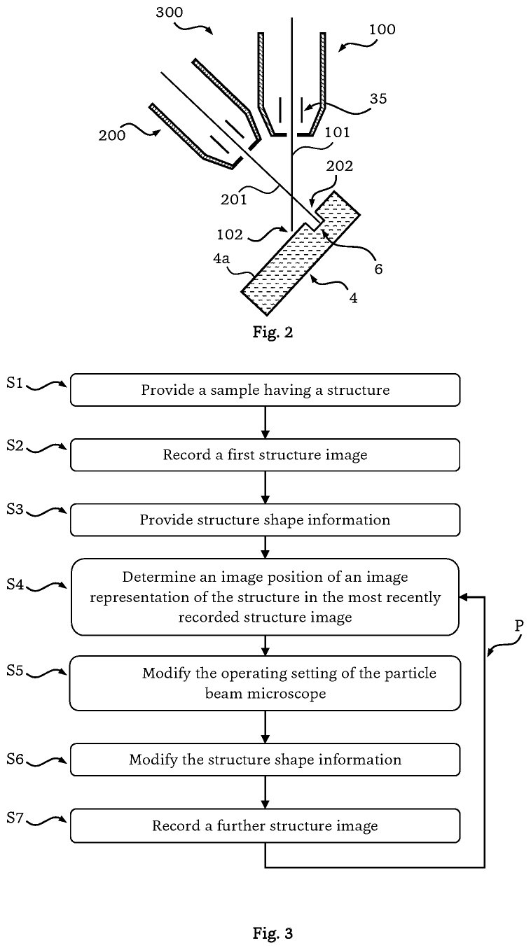

FIG. 2 shows a further particle beam device 300 comprising the particle beam microscope 100 and an ion beam column 200. The ion beam column 200 can have a setup that is identical or similar to that of the particle beam microscope 100 but does not comprise the detector 40. The ion beam column 200 generates an ion beam 201, which can be deflected by a deflection system of the ion beam column 200, so that the ion beam 201 can be directed onto a plurality of different locations on the sample 4. The spatial region into which the ion beam 201 can be directed by the deflection system of the ion beam column 200 is referred to as the work region 202 of the ion beam column 200.

The work region 102 of the particle beam microscope 100 and the work region 202 of the ion beam column 200 can overlap in a common work region. When a structure 6 is generated on the sample 4 in the common work region, an image recorded using the particle beam microscope 100 contains an image representation of the structure 6.

The driver system 60 is further configured to supply the components of the ion beam column 200 with the desired voltages and electric currents. The controller 70 is further configured to control the ion beam column 200 and the components thereof.

In accordance with the above description, the particle beam device 300 comprises a particle beam microscope 100 for recording images of a sample 4, and a controller 70, which is configured to control the particle beam microscope 100 and to perform methods described herein. The particle beam device 300 may further comprise an ion beam column 200, which is controlled by the controller 70, for generating and/or processing the structure 6.

### First Embodiment: Method

A description will be given below of a method for operating a particle beam device according to a first embodiment. FIG. 3 shows a flowchart of an exemplary method for operating the particle beam devices 300 shown in FIGS. 1 and 2.

In step S1, the sample 4 is provided in the work region 102 of the particle beam microscope 100. The sample 4 has, on its surface 4a facing the particle beam microscope 100, a structure 6 (cf. FIG. 2). By way of example, step S1 is performed by an operator of the particle beam device 300, who arranges an appropriate sample 4 in the work region 102 of the particle beam microscope 100. Alternatively, the appropriate sample 4 can be produced by the particle beam device 300.

The structure 6 has been generated on the sample 4 prior to step S1. For example, the structure 6 can be generated by processing the sample 4 using the ion beam 201, when the sample 4 is arranged in the work region 202 of the ion beam column 200 of the particle beam device 300. However, the structure 6 can be generated in any desired manner.

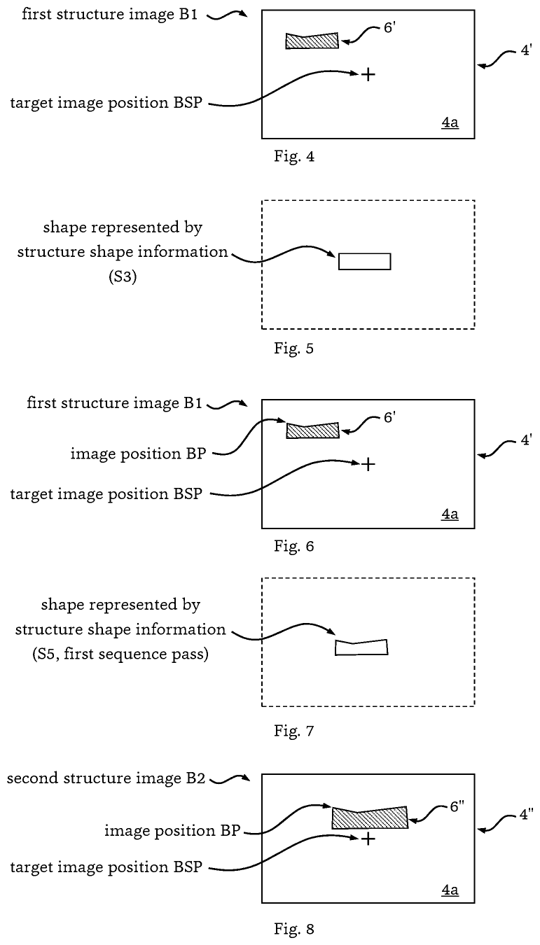

In step S2, which is performed after step S1, a first structure image B1 (FIG. 4), which is an image of the sample 4 that contains an image representation 6′ of the structure 6, is recorded using the particle beam microscope 100. This means that the first structure image B1 represents a spatial region of the sample 4 in which the structure 6 is at least partially situated.

Recording the first structure image B1, as well as all further images recorded using the particle beam microscope 100 in the present method, comprises: raster-scanning the particle beam 101 of the particle beam microscope 100 over the sample 4; detecting interaction products created by the interaction between the particle beam 101 and the sample 4 during the raster-scanning; and generating the respective image on the basis of the detected interaction products. The particle beam 101 of the particle beam microscope 100 is raster-scanned over the sample 4 by virtue of the controller 70 controlling the particle beam microscope 100 in such a manner that the particle beam 101 is generated and directed onto the surface 4a of the sample 4. The particle beam 101 is successively directed onto different locations on the surface 4a of the sample 4, also including locations at which the structure 6 is situated, by virtue of the deflection system 35 successively deflecting the particle beam 101 in different ways.

Interaction products, which are detected by the detector 40, are created by the interaction between the particle beam 101 and the sample 4 during the raster-scanning. The controller 70 associates the detection signal output by the detector 40 with the deflection, as a result of which an image is generated. An image is a data record that assigns a value based on the detection signal to a plurality of deflections (or to a plurality of positions assigned to the deflections). By way of example, an image is a data record that assigns a respective value to a plurality of positions, the value representing a number of detection events when the particle beam is directed onto a location of the sample 4 corresponding to the position.

FIG. 4 shows a schematic example of the first structure image B1, which contains an image representation 4′ of part of the sample 4 and an image representation 6′ of the structure 6. FIG. 4 shows the surface 4a of the sample 4, i.e. a plan view of the surface 4a of the sample 4. In the example shown, the structure 6 or the image representation 6′ thereof has a shape similar to a rectangle, as is the case, for example, when the structure 6 is a material cross section. A cross indicates a target image position BSP. The cross is not contained in the first structure image B1 as a shape element, but is illustrated in the present case in order to simplify understanding.

In step S3 (FIG. 3), which is performed at any desired time prior to step S4, structure shape information is provided, which represents at least part of a shape of the structure 6. The structure shape information is stored in the data memory 90 of the particle beam device 300 and is provided thereby. By way of example, the structure shape information can be defined by an operator of the particle beam device 300. To this end, the operator can define, using the HMI 80, a shape represented by the structure shape information. However, this is merely an example and the definition of the structure shape information is not limited to this example.

FIG. 5 shows a schematic example of the shape represented by the structure shape information provided in step S3. In the example shown, the shape represented by the structure shape information provided in step S3 is a rectangle. In order to relate the size of the shape represented by the structure shape information provided in step S3 to the size of the image representation 6′ of the structure 6 in the first structure image (FIG. 4) for the sake of understanding, a dashed border that is the same size as the first structure image B1 is illustrated.

In step S4 (FIG. 3), which is performed after step S3, an image position BP of the image representation 6′ of the structure 6 in a most recently recorded structure image is determined. Step S4 is performed by the controller 70. When step S4 is performed for the first time, i.e. if step S7 has not yet been performed, the most recently recorded structure image is the first structure image B1 recorded in step S2. When step S4 is performed for the second time and subsequently, i.e. if step S7 has already been performed, the most recently recorded structure image is the further structure image recorded most recently in step S7.

The image position BP represents a position of the image representation of the structure 6 in the most recently recorded structure image. The image position BP is determined by an image feature recognition process executed by the controller 70. The image feature recognition process uses the structure shape information stored in the data memory 90 to recognize the image representation of the structure 6 in the most recently recorded structure image.

By way of example, the image feature recognition process uses a template matching method, which searches for the shape represented by the structure shape information in the most recently recorded structure image and outputs the image position as the result. Template matching is a method for searching for and finding the position of a template image in a larger search image. The template image contains the shape represented by the structure shape information. The search image is the most recently recorded structure image. The method is an iterative method. In each iteration, a similarity measure is calculated, which represents the similarity between the template image and a portion of the search image. The position of the portion relative to the search image differs from iteration to iteration. However, the portion is always the same size. By way of example, a cross correlation between the template image and the respective portion is calculated as the similarity measure. The position of the portion with the highest similarity measure is taken as a basis for determining the image position BP of the image representation of the structure 6 in the most recently recorded structure image.

However, the image feature recognition process is not limited to this example and use may be made of any desired automatic method that is capable of searching for the shape represented by the structure shape information in the most recently recorded structure image, or an image derived from the most recently recorded structure image, and outputting the image position as the result. By way of example, use may be made of a feature-based method that is capable of searching for a feature (here: the shape represented by the structure shape information) in a search image (here: the most recently recorded structure image) and determining the position of the feature in the search image. Such methods may apply artificial intelligence techniques, for example a neural network, classifiers and the like.

FIG. 6 shows a schematic example of the image position BP determined in step S4. The determined image position BP specifies the top left corner of the image representation 6′ of the structure 6 in the first structure image B1. However, this is merely an example and, instead of the top left corner, another position with a known relationship to the shape represented by the structure shape information may be used.

In step S5 (FIG. 3), which is performed after step S4, an operating setting of the particle beam microscope 100 is modified on the basis of the most recently determined image position such that the image position of the image representation of the structure 6 approaches the target image position BSP in a further structure image recorded using the modified operating setting. Step S5 is performed by the controller 70. The target image position BSP is, for example, a position, determined by the operator or a program, in an image. The target image position BSP is, for example, an image centre. As a result of modifying the operating setting, the present method in this example has the effect of moving the image position BSP of the image representation 6′ of the structure 6 into the image centre in a further structure image subsequently recorded with the modified operating setting.

Modifying the operating setting of the particle beam microscope 100 comprises, for example, modifying an operating setting of a particle beam deflection. The particle beam deflection is caused by the deflection system 35.

Modifying the operating setting of the particle beam microscope 100 comprises, for example, modifying an operating setting of the sample stage 5 carrying the sample 4. As a result of modifying the operating setting of the sample stage 5, the sample 4 is moved relative to the particle beam microscope 100.

The operating setting (of the particle beam deflection and of the sample stage 5) is modified in such a manner that a region of the sample 4 that will be or would be raster-scanned by the particle beam 101 during the recording of an image after the operating setting has been modified is shifted relative to a region of the sample 4 that will be or would be raster-scanned by the particle beam 101 during the recording of an image before the operating setting has been modified.

As a result of modifying the operating setting, the present method has the effect that the image representation 6′ of the structure 6 has, in a further structure image subsequently recorded with the modified operating setting, an image position BP that is closer to the target image position BSP than the image position BP determined in step S4. Accordingly, this increases the likelihood of the further image of the sample 4, which has been recorded with the modified operating setting and optionally with increased magnification, containing the structure 6.

Modifying the operating setting of the particle beam microscope 100 may further comprise: modifying an operating setting of a magnification of the particle beam microscope 100, for example increasing the magnification of the particle beam microscope 100. Increasing the magnification in step S5 has the effect that an image recorded subsequently (in step S7) has a higher magnification of the sample 4 than the most recently recorded structure image. The operating setting of the magnification is modified by the controller 70, which controls the deflection system 35 in accordance with the modified operating setting of the magnification. Increasing the magnification means that a distance between scanning positions of the particle beam 101 during the recording of an image becomes smaller. Decreasing the magnification means that the distance between the scanning positions of the particle beam 101 during the recording of an image becomes larger.

In step S6 (FIG. 3), which is performed after step S4 (or, as shown in FIG. 3, after step S5), the structure shape information is modified on the basis of the most recently recorded structure image and/or on the basis of the most recently determined image position BP in step S4. Step S6 is performed by the controller 70 and the deflection system 35.

The structure shape information is for example modified by virtue of the structure shape information being replaced by a portion of the most recently recorded structure image containing the image position BP determined in step S4. To this end, the controller 70 extracts the portion containing the image position BP and thus at least part of the image representation 6′ of the structure 6 from the most recently recorded structure image and replaces the structure shape information stored in the data memory 90 with the extracted portion, which is subsequently used as the structure shape information. Alternatively, the controller 70 can derive a different shape representation from the portion, for example using suitable image processing methods, and store the derived shape representation in the data memory 90 as the structure shape information.

The structure shape information is for example modified by virtue of the controller 70 modifying the structure shape information stored in the data memory 90 on the basis of the most recently recorded structure image or a portion thereof. By way of example, the controller 70 calculates an average image from the structure shape information stored in the data memory 90 and the most recently recorded structure image and stores the calculated average image as the structure shape information in the data memory 90.

FIG. 7 shows a schematic example of the shape represented by the structure shape information modified in step S5. In the example shown, the structure shape information provided in step S3 has been replaced by structure shape information that has been extracted from the first structure image B1 and corresponds to the image representation 6′ of the structure 6. In order to relate the size of the shape represented by the structure shape information modified in step S5 to the size of the image representation 6′ of the structure 6 in the first structure image B1 for the sake of understanding, a dashed border that is the same size as the first structure image B1 is illustrated.

In step S7 (FIG. 3), which is performed after step S5 (or, as shown in FIG. 3, after step S6), a further structure image is recorded using the particle beam microscope 100 using the operating setting modified most recently in step S5. As a result of recording the further structure image using the modified operating setting, an image of the sample 4 is obtained that contains an image representation of the structure 6 and in which the image position BP of the image representation of the structure 6 is closer to the target image position BSP.

FIG. 8 shows a schematic example of a second structure image B2 recorded in step S7 using the operating setting of the particle beam microscope 100 modified in step S5, wherein, inter alia, the magnification of the image recording has been increased. The second structure image B2 therefore represents a smaller region of the sample 4 than the first structure image B1, but has a higher resolution. The second structure image B2 therefore contains a magnified image representation 4″ of part of the sample 4 compared with the first structure B1, and a magnified image representation 6″ of the structure 6. As a result of using the operating setting of the particle beam microscope 100 modified in step S5, the image representation 6″ of the structure 6 (more specifically the image position of the image representation 6″) in the second structure image B2 is closer to the target image position BSP compared with the first structure image B1. On account of the increased magnification of the second structure image B2 compared with the first structure image B1, the image representation 6″ in the second structure image B2 is more detailed than the image representation 6′ in the first structure image B1.

As illustrated in FIG. 3 by an arrow P, steps S4 to S7 form a sequence that is performed repeatedly, wherein in step S4 of the next sequence pass, instead of the image position BP of the image representation 6′ of the structure 6 in the structure image recorded in step S2 (first structure image B1), it is the image position BP of the image representation 6″ of the structure 6 in the structure image recorded in step S7 of the preceding sequence (second structure image B2) that is determined. This means that step S4 is in each case based on the most recently recorded structure image (i.e. the structure image recorded in step S2, if step S7 has not yet been performed; otherwise the structure image most recently recorded in step S7, if step S7 has already been performed).

Accordingly, the method is continued after step S7 of the first sequence pass by performing step S4 of the second sequence pass on the basis of the structure image recorded in step S7 of the first sequence pass, the structure image being the most recently recorded structure image. This means that, when step S4 is performed for the second time and subsequently, after step S7, an image position BP of the image representation of the structure 6 in the structure image recorded in step S7 is determined. In step S4, the image position of the image representation of the structure 6 is determined using the structure shape information obtained when step S5 was most recently performed. FIG. 8 shows a schematic example of the image position BP of the image representation 6″ of the structure 6 determined in step S4 of the second sequence pass.

In step S5 of the second sequence pass, the operating setting of the particle beam microscope 100 is then modified on the basis of the image position BP determined in step S4 of the second sequence pass (FIG. 8).

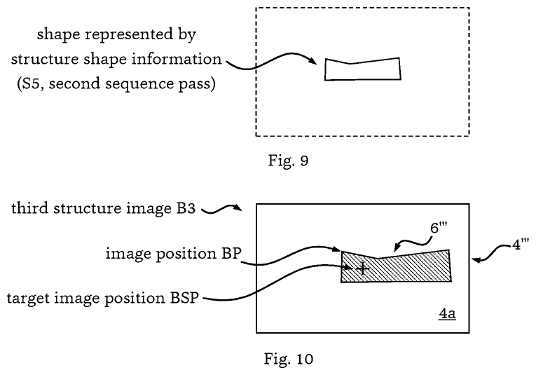

In step S6 of the second sequence pass, the structure shape information is then modified on the basis of the image position BP determined in step S4 of the second sequence pass (FIG. 8) and/or on the basis of the structure image recorded in step S7 of the first sequence pass (second structure image B2). FIG. 9 shows a schematic example of the shape represented by the structure shape information modified in step S5 of the second sequence pass. In the example shown, the structure shape information modified in step S5 of the first sequence pass has been replaced by structure shape information that has been extracted from the second structure image B2 (FIG. 8) and corresponds to the image representation 6″ of the structure 6. In order to relate the size of the shape represented by the structure shape information modified in step S5 to the size of the image representation 6″ of the structure 6 in the second structure image B2 for the sake of understanding, a dashed border that is the same size as the second structure image B2 is illustrated.

In step S7 of the second sequence pass, a further structure image is recorded using the particle beam microscope 100 using the operating setting modified in step S5 of the second sequence pass. FIG. 10 shows a schematic example of a third structure image B3 recorded in step S7 of the second sequence pass using the operating setting of the particle beam microscope 100 modified in step S5 of the second sequence pass, wherein, inter alia, the magnification of the image recording has been increased again. The third structure image B3 therefore represents a smaller region of the sample 4 than the second structure image B2, but has a higher resolution. The third structure image B3 therefore contains a magnified image representation 4″′ of part of the sample 4 compared with the second structure image B2, and a magnified image representation 6″′ of the structure 6. Once again, the image representation 6″′ of the structure 6 (more specifically the image position of the image representation 6″′) in the third structure image B3 is closer to the target image position BSP compared with the second structure image B2. On account of the increased magnification of the third structure image B3 compared with the second structure image B2, the image representation 6″′ in the third structure image B3 is more detailed than the image representation 6″ in the second structure image B2.

Each time steps S7, S4 and S6 are performed, the structure shape information is updated and adapted to possibly changing conditions on the surface 4a of the sample 4. By way of example, if the magnification of the image recording in step S5 is modified, the structure shape information is adapted to the modified magnification. This makes it possible to efficiently track the image position BP of the image representation of the structure 6.

As already described above, steps S4 to S7 of the sequence are performed by the controller 70. Accordingly, the controller 70 can perform the sequence fully automatically without requiring the intervention of an operator. This makes it easier to record an image with high magnification of the structure 6 on the sample 4 using a particle beam microscope 100.

The method may further comprise: focusing the particle beam microscope 100, for example while the sequence is being performed (in step S5) and/or after the sequence has been performed (between step S7 and step S4). By way of example, focusing is performed before step S2 and/or before S7. The focusing is performed, for example, by modifying the operating setting of the objective lens 30, for example by modifying an electric current supplied to the excitation coil 32. In addition to or as an alternative to the focusing of the particle beam microscope 100, the method may further comprise: modifying an astigmatism of the particle beam 101. For this purpose, the particle beam microscope 100 may comprise a stigmator, which can be controlled by the controller 70 and is formed, for example, of coils.

A description has been given above of an example of a method for operating a particle beam system in which a magnified image of an individual structure 6 on the sample 4 is automatically recorded. However, the method for operating the particle beam system is not limited to this example and can be applied to recording magnified images of a plurality of different spatially distanced structures on the sample. In this case, the method is performed successively for the different structures and with optionally different initial structure shape information.

A description has been given above of an example of a method for operating a particle beam system in which the structure is defined only to such an extent that it is recognizable in an image recorded using the particle beam microscope 100. However, the method is particularly suitable for more specific structures. By way of example, the method is particularly suitable for structures that are material cross sections. A material cross section is a region of a sample situated at a cutout in the sample. The cutout is produced by removing material from the sample. The surface of the cutout that forms the material cross section is oriented obliquely, for example substantially perpendicularly, with respect to the surface of the sample surrounding the cutout.

A description has been given above of an example of a method for operating a particle beam system in which, in step S1, a sample 4 having a structure 6 is provided. This means that the sample 4 already has the structure 6 at the start of the method. However, the method is not limited to this example and the structure 6 may be generated and/or processed on the sample 4 using the particle beam device 300.

For example, the sequence further comprises, before the further structure image is recorded (step S7): processing the structure 6 in the work region 102 of the particle beam microscope 100 by removing material from the sample 4 using the particle beam device 300 and/or by depositing material on the sample 4 using the particle beam device 300. The structure 6 may be, for example, processed using the particle beam 101 of the particle beam microscope 100 or the ion beam 201 of the ion beam column 200.

### Second Embodiment: Method

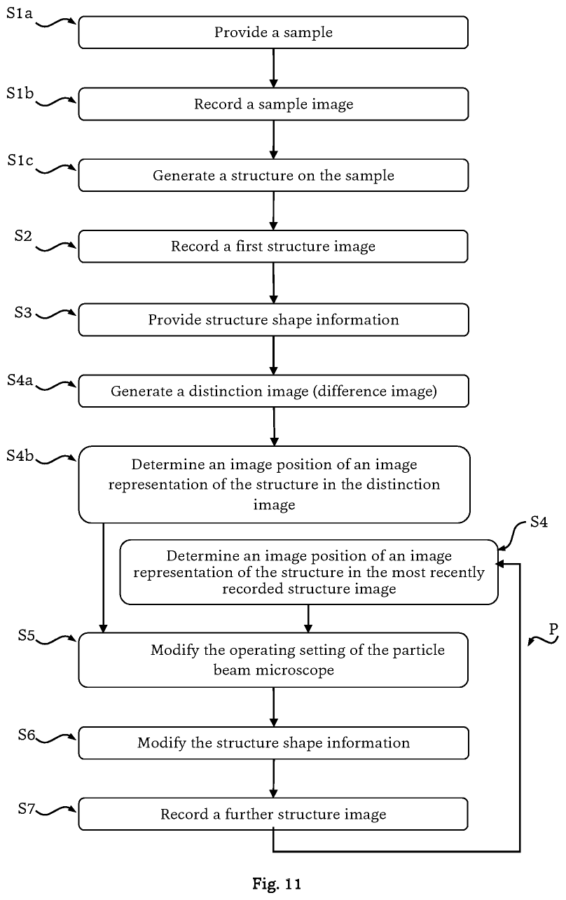

A description will be given below of a method for operating a particle beam device according to a second embodiment. FIG. 11 shows a flowchart of the method for operating the particle beam device 300 shown in FIG. 2. Those method steps of the method according to the second embodiment shown in FIG. 11 that are identical to those in the method according to the first embodiment shown in FIG. 3 are denoted by the same reference signs and the description thereof will not be repeated below. Instead, reference is made to the detailed description of the respective method steps of the first embodiment.

In step S1a, which is the first step of the method, the sample 4 is provided without a (subsequently generated) structure 6 in the work region 102 of the particle beam microscope 100. This means that the sample 4 provided in step S1a does not yet comprise the structure 6, which is subsequently generated in step S1c. However, the sample 4 provided in step S1a may comprise other structures 8. The other structures 8 may have any desired shapes, for example may also have the same shape as the (subsequently generated) structure 6. By way of example, step S1a is performed by an operator of the particle beam device 300.

In step S1b, which is performed after step S1a, a sample image B0, which is an image of the sample 4 provided in step S1a, is recorded using the particle beam microscope 100.

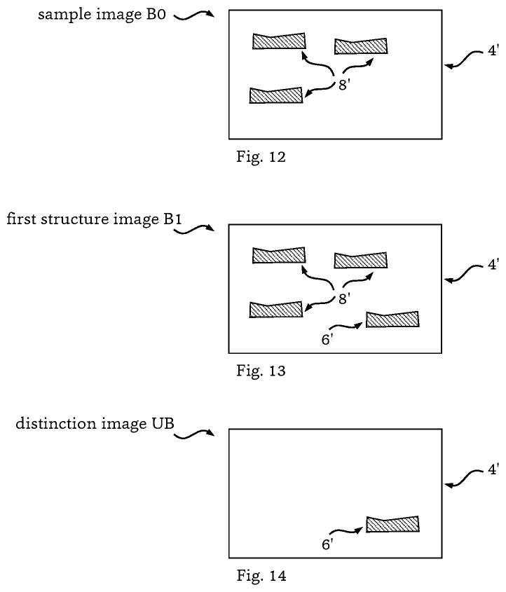

FIG. 12 shows a schematic illustration of a sample image B0 recorded in step S1b. The sample image B0 contains image representations 8′ of the structures 8, which are different from the structure 6 (but have the same shape in the present case).

In step S1c, which is performed after step S1b, the structure 6 is generated on the surface 4a of the sample 4 using the particle beam device 300, for example by removing material from the sample 4 using the particle beam device 300 and/or by depositing material on the sample 4 using the particle beam device 300. The structure 6 may be, for example, generated using the particle beam 101 of the particle beam microscope 100 or by the ion beam 201 of the ion beam column 200. As a result of step S1c, the sample 4 having the structure 6 is provided in the work region 102 of the particle beam microscope 100 (corresponding to step S1 of the first embodiment).

After step S1c, step S2 (FIG. 11) is performed as described in the first embodiment. FIG. 13 shows a schematic illustration of the first structure image B1 recorded in step S2. The first structure image B1 has been recorded (without loss of generality) with the same magnification as the sample image B0. The first structure image B1 contains the image representations 8′ of the structures 8 and an image representation 6′ of the structure 6 generated in step S1c.

After step S2, step S3 (FIG. 11) is performed as described in the first embodiment.

In step S4a (FIG. 11), which is performed after step S2 (or, as shown in FIG. 11, after step S3), a distinction image UB, which represents distinctions between the sample image B0 recorded in step S1b and the first structure image B1 recorded in step S2, is generated by comparing the sample image B0 with the recorded first structure image B1. Step S4a is performed by the controller 70. Any known method capable of identifying distinctions between images may be used to determine the distinctions between the sample image B0 and the first structure image B1. By way of example, a difference image, which represents a difference between the sample image B0 and the recorded first structure image B1, may be generated as the distinction image UB. In this case, the difference is, for example, a pixel-by-pixel difference if the images to be compared consist of pixels.

FIG. 14 shows a schematic illustration of a distinction image UB, which illustrates the distinctions between the sample image B0 recorded in step S1b and the first structure image B1 recorded in step S2. The distinction image UB comprises solely the image representation 6′ of the structure 6 generated in step S1c.

In order to improve the distinction image UB or difference image, the controller 70 can optimize the sample image B0 and/or the first structure image B1 for the comparison between them (step S4a), and the distinction image UB or difference image can then be generated on the basis of the optimized images.

In step S4b, which is performed after step S4a, the image position of the image representation 6′ of the structure 6 is determined using an image feature recognition process, which uses the structure shape information provided in step S3 to recognize the image representation 6′ of the structure 6 generated in step S1c in the distinction image UB. Step S4b is performed by the controller 70. In order to improve the comparison with the structure shape information (step S4b), the controller 70 can optimize, using image processing, the distinction image UB or difference image for the comparison. The image feature recognition process in step S4b and the image feature recognition process in step S4 (FIG. 11) may be identical, apart from the fact that they are applied to different images. Reference is made to the description of the details of the image feature recognition process in step S4 of the first embodiment. Alternatively, the image feature recognition process in step S4b and the image feature recognition process in step S4 (FIG. 11) may be fundamentally different image feature recognition processes from one another.

After step S4b, steps S5 to S7 are performed as described in the first embodiment. As illustrated by an arrow P in FIG. 11, step S4 is performed after step S7. Steps S4 to S7 form, as in the first embodiment, a sequence that is performed repeatedly. Reference is made to the details of steps S4 to S7 of the first embodiment.

As a result of steps S4a and S4b, the method according to the second embodiment offers the desirable feature of being able to easily distinguish the structure 6 newly generated on the sample 4 in step S1c from other similar structures already present on the sample 4 in step S1a and to locate the image position of the structure. This makes it easier to determine the image position of the image representation 6′ of the structure 6 newly generated in step S1c in the first structure image B1 recorded in step S2.

Moreover, a method according to the second embodiment can offer the same desirable features as a method according to the first embodiment.

### List of reference signs

4 Sample
4a Surface of the sample
4′, 4″, 4″′ Image representation of part of the sample
5 Sample stage
6 Structure
6′, 6″, 6″′, 8′ Image representation of a structure
10 Particle beam generator
11 Particle source
12 Suppression electrode
13 Extraction electrode
14 Housing
15 Insulator
21 Anode stop
22 Aperture of the anode stop
23 Beam tube
30 Objective lens
31 Magnetic core
32 Excitation coil
35 Deflection system
36, 37 Deflection unit
40 Detector
50 Condenser
51 Magnetic core
52 Excitation coil
60 Driver system
61, 62 Line
70 Controller
80 Human-machine interface
90 Data memory
100 Particle beam microscope
101 Particle beam
102 Work region of the particle beam microscope
200 Ion beam column
201 Ion beam
202 Work region of the ion beam column
300 Particle beam device
B0 Sample image
B1, B2, B3 Structure image
BSP Target image position
BP Image position
P Arrow
UB Distinction image

What is claimed is:

1. A method of operating a particle beam device comprising a particle beam microscope, the method comprising:
providing a sample, which comprises a structure on a surface, in a work region of the particle beam microscope;
recording a first structure image, which is an image of the sample that comprises an image representation of at least part of the structure, using the particle beam microscope;
providing structure shape information that represents at least part of a shape of the structure;
performing a sequence, which comprises:
determining an image position, which represents a position of the image representation of the structure in a most recently recorded structure image, using a first image feature recognition process, which uses the structure shape information to recognize the image representation of the structure in the most recently recorded structure image;
modifying an operating setting of the particle beam microscope based on the most recently determined image position so that the image position of the image representation of the structure approaches a target image position in a further structure image recorded using the modified operating setting, wherein modifying the operating setting of the particle beam microscope comprises modifying an operating setting of a particle beam deflection of the particle beam microscope and/or modifying an operating setting of a sample stage carrying the sample;
modifying the structure shape information based on the most recently recorded structure image and/or based on the most recently determined image position; and
recording a further structure image using the particle beam microscope using the most recently modified operating setting; and
repeating the sequence using the recorded further structure image as the most recently recorded structure image.

2. The method of claim 1, wherein providing the sample having the structure comprises generating the structure on the surface of the sample by removing material from the sample using the particle beam device and/or by depositing material on the sample using the particle beam device, and wherein the method further comprises:
providing the sample without the structure in the work region of the particle beam microscope;
recording a sample image, which is an image of the sample without the structure, using the particle beam microscope;
generating a distinction image, which represents distinctions between the sample image and the first structure image, by comparing the sample image with the first structure image; and
determining the image position using a second image feature recognition process, which uses the structure shape information to recognize the image representation of the structure in the distinction image.

3. The method of claim 2, wherein generating the distinction image comprises generating a difference image, which represents a difference between the sample image and the first structure image, as the distinction image.

4. The method of claim 3, wherein the image feature recognition process further comprises using image processing to optimize:
the sample image and/or the first structure image for the comparison between the sample image and the first structure image; and/or
the distinction image for the comparison with the structure shape information.

5. The method of claim 2, wherein the image feature recognition process further comprises using image processing to optimize:
the sample image and/or the first structure image for the comparison between the sample image and the first structure image; and/or
the distinction image for the comparison with the structure shape information.

6. The method of claim 1, wherein modifying the structure shape information comprises:
modifying the structure shape information based on of a portion of the most recently recorded structure image that comprises the most recently determined image position; and/or
replacing the structure shape information with a portion of the most recently recorded structure image that comprises the most recently determined image position, or with a shape representation derived from the portion.

7. The method of claim 1, wherein the target image position is a predetermined position in an image.

8. The method of claim 7, wherein the predetermined position in the image is an image centre.

9. The method of claim 1, wherein modifying the operating setting of the particle beam microscope further comprises modifying an operating setting of a magnification of the particle beam microscope.

10. The method of claim 1, wherein modifying the operating setting of the particle beam microscope further comprises increasing a magnification of the particle beam microscope.

11. The method of claim 1, wherein the sequence is performed automatically by a controller of the particle beam microscope.

12. The method of claim 1, further comprising focusing the particle beam microscope while the sequence is being performed and/or after the sequence has been performed.

13. The method of claim 1, wherein the method is performed repeatedly for different spatially distanced structures on the sample.

14. The method of claim 1, wherein the structure comprises a material cross section oriented obliquely with respect to the surface of the sample.

15. The method of claim 1, wherein the sequence further comprises, before the further structure image is recorded, processing the structure in the work region of the particle beam microscope by removing material from the sample using the particle beam device and/or by depositing material on the sample using the particle beam device.

16. The method of claim 15, wherein the structure is processed using a particle beam of the particle beam microscope or an ion beam of an ion beam column of the particle beam device.

17. The method of claim 1, wherein recording each of the images comprises:
raster-scanning a particle beam of the particle beam microscope over the sample;
detecting interaction products created by the interaction between the particle beam and the sample during the raster-scanning; and
generating the respective image based on the detected interaction products.

18. One or more machine-readable hardware storage devices comprising instructions that are executable by one or more processing devices to perform operations comprising the method of claim 1.

19. A system, comprising:
one or more processing devices; and
one or more machine-readable hardware storage devices comprising instructions that are executable by the one or more processing devices to perform operations comprising the method of claim 1.

20. The system of claim 19, further comprising an ion beam column configured to generate and/or process the structure, wherein the work region of the particle beam microscope and a work region of the ion beam column overlap in a common work region.
